(19) United States
(12) Patent Application Publication
(10) Pub. No.: US 2023/0049429 A1
(43) Pub. Date: Feb. 16, 2023

(54) METAL OXIDE FILM-FORMING COMPOSITION AND METHOD OF PRODUCING METAL OXIDE FILM USING THE COMPOSITION

(71) Applicant: TOKYO OHKA KOGYO CO., LTD., Kawasaki-shi (JP)

(72) Inventors: Kunihiro NODA, Kawasaki-shi (JP); Kenichi YAMAUCHI, Kawasaki-shi (JP); Michihito TAKAHASHI, Kawasaki-shi (JP); Atsushi YAMANOUCHI, Kawasaki-shi (JP); Dai SHIOTA, Kawasaki-shi (JP)

(21) Appl. No.: 17/808,218

(22) Filed: Jun. 22, 2022

(30) Foreign Application Priority Data
Jun. 30, 2021 (JP) 2021-109098

(51) Int. Cl. G03F 1/38; G03F 1/80

(52) U.S. Cl. CPC G03F 1/38; G03F 1/80

(57) ABSTRACT

A metal oxide film-forming composition including a tertiary alkyloxycarbonyloxy group-containing aromatic hydrocarbon ring-modified fluorene compound represented by Formula (1) below; metal oxide nanoparticles surface-treated with a capping agent; and a solvent. In the formula, ring Z¹ represents an aromatic hydrocarbon ring, R^{1a} and R^{1b} each independently represents a halogen atom, a cyano group, or an alkyl group, R^{2a} and R^{2b} each independently represents an alkyl group, R^{3a}, R^{3b}, R^{4a}, R^{4b}, R^{5a}, and R^{5b} each independently represents an alkyl group having 1 to 8 carbon atoms, k1 and k2 each independently represents an integer of 0 or more and 4 or less, and m1 and m2 each independently represents an integer of 0 or more and 6 or less

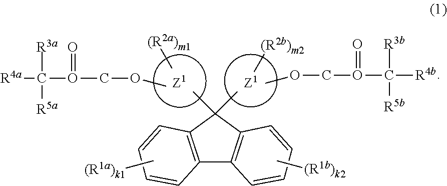

This application claims priority to Japanese Patent Application No. 2021-109098, filed Jun. 30, 2021, the entire content of which is incorporated herein by reference.

### BACKGROUND OF THE INVENTION

### Field of the Invention

The present invention relates to a metal oxide film-forming composition and a method of producing a metal oxide film using the composition.

### Related Art

A typical process for manufacturing semiconductor devices or other devices involves an etching process that includes applying a resist material, such as a photoresist or an electron beam resist, to the surface of a substrate as an etching target; patterning the resist by lithography to form a patterned resist film; and etching the substrate using the patterned resist film as an etching mask to form a desired pattern on the substrate.

In such a process, some etch rates for the etching of the substrate may cause a problem with etch selectivity of the substrate over the resist film and make it impossible for the resist film to sufficiently function as the etching mask. To address such a problem, a certain process for etching the substrate is used which includes forming an etching mask called a hard mask to attain a high etch selectivity of the substrate over the etching mask. An example of a known hard mask includes a metal oxide film including metal oxide nanoparticles, such as zirconium oxide nanoparticles (see Patent Document 1).
Patent Document 1: Japanese Unexamined Patent Application (Translation of PCT Application), Publication No. 2020-503409

### SUMMARY OF THE INVENTION

Conventional metal oxide films including metal oxide nanoparticles are formed by heating a coating consisting of a composition including metal oxide nanoparticles. As a result of an investigation, the inventors have found that conventional metal oxide films are prone to cracking when fired at 400° C. or more (e.g., fired at 450° C.) or have an insufficient level of dry etching resistance.

The present invention has been made in light of such existing circumstances. It is an object of the present invention to provide a metal oxide film-forming composition capable of forming a metal oxide film that is less likely to crack when fired at 400° C. or more and has high dry etching resistance, and to provide a method of producing a metal oxide film using such a composition.

To solve the problems mentioned above, the inventors have made intensive studies. As a result, the inventors have completed the present invention based on findings that the problems can be solved with a metal oxide film-forming composition including: a specific protecting group-containing compound capable of generating a carboxy or hydroxy group upon deprotection by heating, such as a specific tertiary alkyloxycarbonyloxy group-containing aromatic hydrocarbon ring-modified fluorene compound; metal oxide nanoparticles surface-treated with a capping agent; and a solvent. Specifically, the present invention provides the following aspects.

A first aspect of the present invention is directed to a metal oxide film-forming composition including: a tertiary alkyloxycarbonyloxy group-containing aromatic hydrocarbon ring-modified fluorene compound represented by Formula (1) below; metal oxide nanoparticles surface-treated with a capping agent; and a solvent.

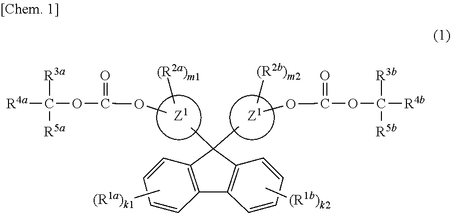

### In Formula (1),

ring Z¹ represents an aromatic hydrocarbon ring, Ria and Rib each independently represent a halogen atom, a cyano group, or an alkyl group, R^{2a} and R^{2b} each independently represent an alkyl group, R^{3a}, R^{3b}, R^{4a}, R^{4b}, R^{5a}, and R^{5b} each independently represent an alkyl group having 1 to 8 carbon atoms, k1 and k2 each independently represent an integer of 0 or more and 4 or less, and m1 and m2 each independently represent an integer of 0 or more and 6 or less.

A second aspect of the present invention is directed to a metal oxide film-forming composition including: an aromatic hydrocarbon ring-modified fluorene compound having a carboxy or hydroxy group-protecting group; metal oxide nanoparticles surface-treated with a capping agent; and a solvent.

A third aspect of the present invention is directed to a method of producing a metal oxide film, the method including: forming a coating including the metal oxide film-forming composition according to the first or second aspect; and heating the coating.

The present invention makes it possible to provide a metal oxide film-forming composition capable of forming a metal oxide film that is less likely to crack when fired at 400° C. or more and has high dry etching resistance, and to provide a method of producing a metal oxide film using such a composition.

### DETAILED DESCRIPTION OF THE INVENTION

### Metal Oxide Film-Forming Composition

The metal oxide film-forming composition according to the first aspect of the present invention includes a tertiary alkyloxycarbonyloxy group-containing aromatic hydrocarbon ring-modified fluorene compound represented by Formula (1); metal oxide nanoparticles surface-treated with a capping agent; and a solvent. The metal oxide film-forming composition according to the second aspect of the present invention includes an aromatic hydrocarbon ring-modified fluorene compound having a carboxy or hydroxy group-protecting group; metal oxide nanoparticles surface-treated with a capping agent; and a solvent. The metal oxide film-forming composition according to the present invention is capable of forming a metal oxide film that is less likely to crack when fired at 400° C. or more and has high dry etching resistance.

In the metal oxide film-forming composition according to the second aspect of the present invention, the aromatic hydrocarbon ring-modified fluorene compound may be a tertiary alkyloxycarbonyloxy group-containing aromatic hydrocarbon ring-modified fluorene compound represented by Formula (1) and/or an organooxy group-containing aromatic hydrocarbon ring-modified fluorene compound represented by Formula (2) shown below. The carboxy or hydroxy group-protecting group may be, for example, a protecting group capable of undergoing deprotection by heating to give a carboxy or hydroxy group.

### Tertiary Alkyloxycarbonyloxy Group-Containing Aromatic Hydrocarbon Ring-Modified Fluorene Compound Represented by Formula (1)

One, two, or more tertiary alkyloxycarbonyloxy group-containing aromatic hydrocarbon ring-modified fluorene compounds represented by Formula (1) may be used alone or in combination with one another.

In Formula (1), the aromatic hydrocarbon ring represented by ring Z¹ is typically, but not limited to, a naphthalene ring or a benzene ring.

Examples of the halogen atom for R^{1a} and R^{1b} in Formula (1) include a chlorine atom, a fluorine atom, a bromine atom, and an iodine atom. The alkyl group for R^{1a} and R^{1b} in Formula (1) may be linear or branched, and examples of the alkyl group include alkyl groups having 1 or more and 6 or less carbon atoms, such as methyl, ethyl, propyl, isopropyl, butyl, and tert-butyl groups. R^{1a} and R^{1b} may be the same or different. When k1 is 2 or more, two or more R^{1a} may be the same or different. When k2 is 2 or more, two or more R^{1b} may be the same or different. The symbols k1 and k2 are each independently an integer of 0 or more and 4 or less, preferably 0 or 1, or preferably 0. The symbols k1 and k2 may be the same or different.

The alkyl group for R^{2a} and R^{2b} in Formula (1) may be linear or branched, and examples of the alkyl group include alkyl groups having 1 or more and 18 or less carbon atoms, such as methyl, ethyl, propyl, isopropyl, butyl, tert-butyl, n-pentyl, isopentyl, sec-pentyl, tert-pentyl, n-hexyl, isohexyl, sec-hexyl, and tert-hexyl groups, and are preferably alkyl groups having 1 or more and 8 or less carbon atoms or having 1 or more and 6 or less carbon atoms. R^{2a} and R^{2b} may be the same or different. When m1 is 2, two R^{2a} may be the same or different. When m2 is 2, two R^{2b} may be the same or different. The symbols m1 and m2 are each independently an integer of 0 or more and 6 or less, preferably an integer of 0 or more and 3 or less, more preferably 0 or 1. The symbols m1 and m2 may be the same or different.

Examples of the alkyl group having 1 to 8 carbon atoms for R^{3a}, R^{3b}, R^{4a}, R^{4b}, R^{5a}, and R^{5b} in Formula (1) include, but are not limited to, methyl, ethyl, propyl, isopropyl, butyl, tert-butyl, n-pentyl, isopentyl, sec-pentyl, tert-pentyl, n-hexyl, isohexyl, sec-hexyl, tert-hexyl, n-heptyl, and n-octyl groups, among which for ease of synthesis and for stability, alkyl groups having 1 or more and 6 or less carbon atoms are preferred, such as methyl, ethyl, propyl, isopropyl, butyl, tert-butyl, n-pentyl, isopentyl, sec-pentyl, tert-pentyl, n-hexyl, isohexyl, sec-hexyl, and tert-hexyl groups, alkyl groups having 1 or more and 3 or less carbon atoms are more preferred, such as methyl, ethyl, propyl, and isopropyl groups, and a methyl group is even more preferred.

The tertiary alkyloxycarbonyloxy group-containing aromatic hydrocarbon ring-modified fluorene compound represented by Formula (1) may be, for example, a tertiary alkyloxycarbonyl group-modified bisnaphthol fluorene compound represented by Formula (1-1) below or a tertiary alkyloxycarbonyl group-modified bisphenol fluorene compound represented by Formula (1-2) below. It should be noted that in Formula (1-1), there are two six-membered rings in the naphthalene ring: one bonded to the fluorene ring and the other not bonded to the fluorene ring and that each of R^{2a}, R^{2b}, —O—CO—O—C(R^{3a}) (R^{4a}) (R^{5a}), and —O—CO—O—C(R^{3b}) (R^{4b}) (R^{5b}), which is bonded to the naphthalene ring, is bonded to the other six-membered ring not bonded to the fluorene ring.

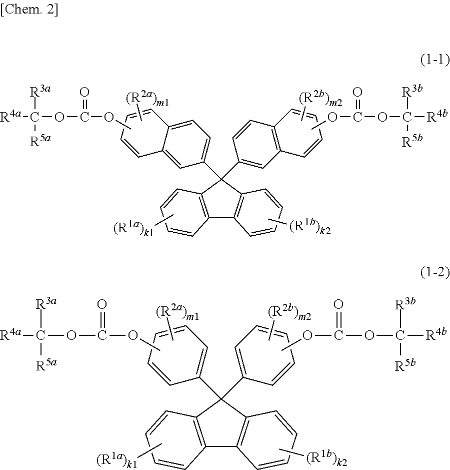

In the formulae, R^{1a}, R^{1b}, R^{2a}, R^{2b}, R^{3a}, R^{3b}, R^{4a}, R^{4b}, R^{5a}, R^{5b}, k1, k2, m1, and m2 are as defined above.

Examples of the tertiary alkyloxycarbonyloxy group-containing aromatic hydrocarbon ring-modified fluorene compound represented by Formula (1) include, but are not limited to, those shown below.

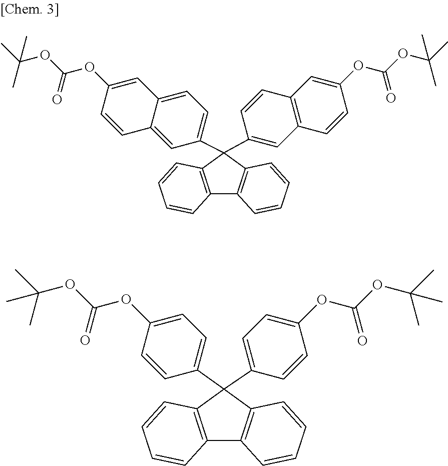

### Organooxy Group-Containing Aromatic Hydrocarbon Ring-Modified Fluorene Compound Represented by Formula (2)

One, two, or more organooxy group-containing aromatic hydrocarbon ring-modified fluorene compounds represented by Formula (2) below may be used alone or in combination with one another.

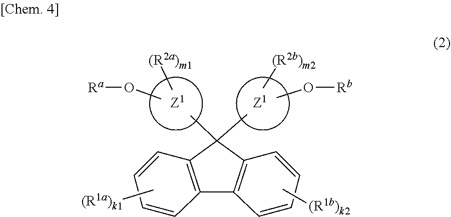

### In Formula (2),

ring Z¹, R^{1a}, R^{1b}, R^{2a}, R^{2b}, k1, k2, m1, and m2 are as defined above, and R^{a} and R^{b} are each independently a group represented by Formula (4), (5), or (6) below.

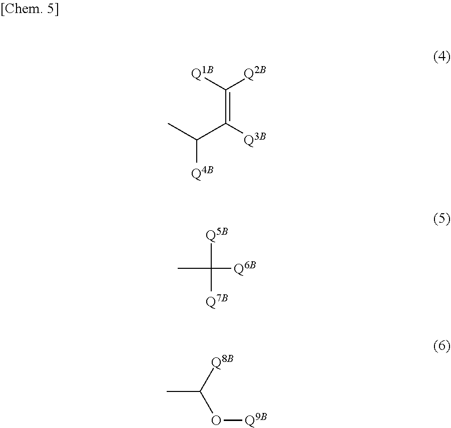

In the formulae, Q^{1B}, Q^{2B}, Q^{3B}, and Q^{4B} are each a hydrogen atom or an alkyl group having 1 to 20 carbon atoms, any two selected from the substituents represented by Q^{1B}, Q^{2B}, Q^{3B}, and Q^{4B} may be bonded to each other to form a cyclic substituent, Q^{5B}, Q^{6B}, and Q^{7B} are each an alkyl group having 1 to 20 carbon atoms, any two selected from the substituents represented by Q^{5B}, Q^{6B}, and Q^{7B} may be bonded to each other to form a cyclic substituent, Q^{8B} and Q^{9B} are each an alkyl group having 1 to 20 carbon atoms, and Q^{8B} and Q^{9B} may be bonded to each other to form a cyclic substituent.

Examples of the alkyl group having 1 to 20 carbon atoms for Q^{1B}, Q^{2B}, Q^{3B}, and Q^{4B} in Formula (4) include, but are not limited to, methyl, ethyl, propyl, isopropyl, butyl, tert-butyl, n-pentyl, isopentyl, sec-pentyl, tert-pentyl, n-hexyl, isohexyl, sec-hexyl, tert-hexyl, n-heptyl, n-octyl, n-decyl, n-dodecyl, n-octadecyl, and n-icosyl groups, among which for ease of synthesis and for stability, alkyl groups having 1 or more and 6 or less carbon atoms are preferred, such as methyl, ethyl, propyl, isopropyl, butyl, tert-butyl, n-pentyl, isopentyl, sec-pentyl, tert-pentyl, n-hexyl, isohexyl, sec-hexyl, and tert-hexyl groups, alkyl groups having 1 or more and 3 or less carbon atoms are more preferred, such as methyl, ethyl, propyl, and isopropyl groups, and methyl and ethyl groups are even more preferred.

Any two selected from the substituents represented by Q^{1B}, Q^{2B}, Q^{3B}, and Q^{4B} may be bonded to each other to form a cyclic substituent. In this case, the cyclic substituent may be, for example, a cycloalkane ring, a cycloalkene ring, a group formed by elimination of two or three hydrogen atoms from a bridged carbocyclic ring, or a group formed by elimination of two hydrogen atoms from an aromatic hydrocarbon ring.

Examples of the alkyl group having 1 to 20 carbon atoms for Q^{5B}, Q^{6B}, and Q^{7B} in Formula (5) include, but are not limited to, methyl, ethyl, propyl, isopropyl, butyl, tert-butyl, n-pentyl, isopentyl, sec-pentyl, tert-pentyl, n-hexyl, isohexyl, sec-hexyl, tert-hexyl, n-heptyl, n-octyl, n-decyl, n-dodecyl, n-octadecyl, and n-icosyl groups, among which for ease of synthesis and for stability, alkyl groups having 1 or more and 6 or less carbon atoms are preferred, such as methyl, ethyl, propyl, isopropyl, butyl, tert-butyl, n-pentyl, isopentyl, sec-pentyl, tert-pentyl, n-hexyl, isohexyl, sec-hexyl, and tert-hexyl groups, alkyl groups having 1 or more and 3 or less carbon atoms are more preferred, such as methyl, ethyl, propyl, and isopropyl groups, and methyl and ethyl groups are even more preferred.

Any two selected from the substituents represented by Q^{5B}, Q^{6B}, and Q^{7B} may be bonded to each other to form a cyclic substituent. In this case, the cyclic substituent may be, for example, a cycloalkane ring, a cycloalkene ring, or a group formed by elimination of two hydrogen atoms from a bridged carbocyclic ring.

Examples of the alkyl group having 1 to 20 carbon atoms for Q^{8B} and Q^{9B} in Formula (6) include, but are not limited to, methyl, ethyl, propyl, isopropyl, butyl, tert-butyl, n-pentyl, isopentyl, sec-pentyl, tert-pentyl, n-hexyl, isohexyl, sec-hexyl, tert-hexyl, n-heptyl, n-octyl, n-decyl, n-dodecyl, n-octadecyl, and n-icosyl groups, among which for ease of synthesis and for stability, alkyl groups having 1 or more and 6 or less carbon atoms are preferred, such as methyl, ethyl, propyl, isopropyl, butyl, tert-butyl, n-pentyl, isopentyl, sec-pentyl, tert-pentyl, n-hexyl, isohexyl, sec-hexyl, and tert-hexyl groups, alkyl groups having 1 or more and 3 or less carbon atoms are more preferred, such as methyl, ethyl, propyl, and isopropyl groups, and methyl and ethyl groups are even more preferred.

Q^{8B} and Q^{9B} may be bonded to each other to form a cyclic substituent. In this case, the cyclic substituent may be, for example, a group formed by elimination of one hydrogen atom from a cyclic ether compound.

The organooxy group-containing aromatic hydrocarbon ring-modified fluorene compound represented by Formula (2) may be, for example, an organooxy group-containing aromatic hydrocarbon ring-modified fluorene compound represented by Formula (2-1) below or an organooxy group-containing aromatic hydrocarbon ring-modified fluorene compound represented by Formula (2-2) below. It should be noted that in Formula (2-1), there are two six-membered rings in the naphthalene ring: one bonded to the fluorene ring and the other not bonded to the fluorene ring and that each of R^{2a}, R^{2b}, —O—R^{a}, and —O—R^{b}, which is bonded to the naphthalene ring, is bonded to the other six-membered ring not bonded to the fluorene ring.

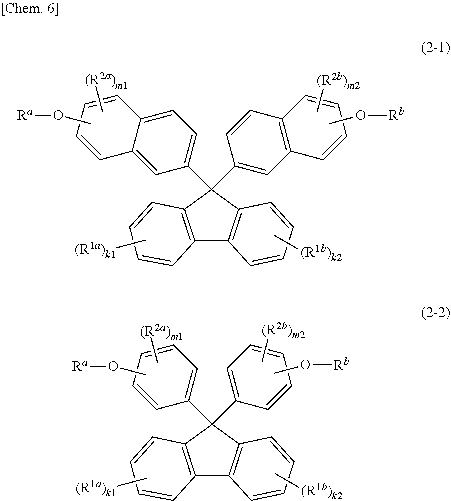

In the formulae, R^{1a}, R^{1b}, R^{2a}, R^{2b}, R^{a}, R^{b}, k1, k2, m1, and m2 are as defined above.

Examples of the organooxy group-containing aromatic hydrocarbon ring-modified fluorene compound represented by Formula (2) include, but are not limited to, those shown below.

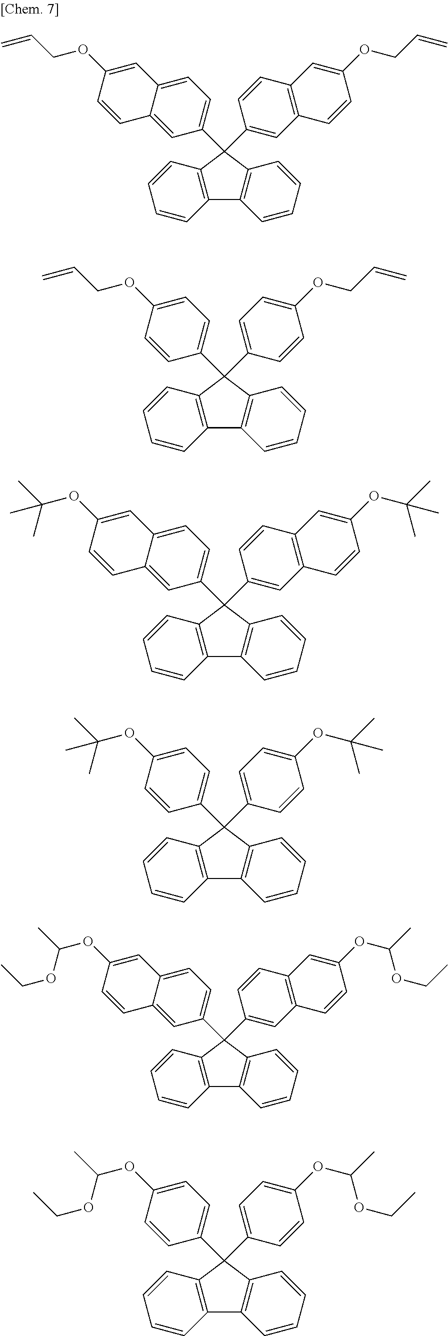

The amount of the aromatic hydrocarbon ring-modified fluorene compound represented by Formula (1) or (2) is preferably, but not limited to, 1 to 95% by mass (e.g., 1 to 50% by mass or 2 to 70% by mass), more preferably 2 to 40% by mass (e.g., 3 to 40% by mass), based on the total amount of the non-solvent components of the metal oxide film-forming composition. With the amount of the aromatic hydrocarbon ring-modified fluorene compound represented by Formula (1) or (2) falling within such a range, the composition can easily form a metal oxide film that is less likely to crack when fired at 400° C. or more and has high dry etching resistance.

### Method of Producing the Tertiary Alkyloxycarbonyloxy Group-Containing Aromatic Hydrocarbon Ring-Modified Fluorene Compound Represented by Formula (1)

The tertiary alkyloxycarbonyloxy group-containing aromatic hydrocarbon ring-modified fluorene compound represented by Formula (1) may be produced, for example, by reacting a hydroxy group-containing aromatic hydrocarbon ring-modified fluorene compound represented by Formula (7) below with a di(tertiary alkyl) dicarbonate compound represented by Formula (8) below. For example, the reaction may be carried out in a solvent (e.g., an alkyl halide solvent such as dichloromethane, an ether solvent such as tetrahydrofuran (THF), or an alcohol solvent such as methanol) in the presence of a base (e.g., an organic base such as triethylamine, pyridine, or N,N-dimethyl-4-aminopyridine).

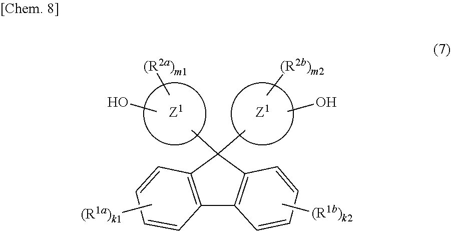

In the formula, Z¹, R^{1a}, R^{1b}, R^{2a}, R^{2b}, k1, k2, m1, and m2 are as defined above.

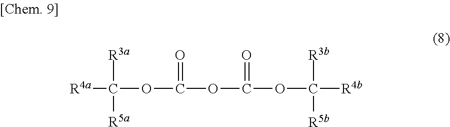

In the formula, R^{3a}, R^{3b}, R^{4a}, R^{4b}, R^{5a}, and R^{5b} are as defined above.

### Method of Producing the Organooxy Group-Containing Aromatic Hydrocarbon Ring-Modified Fluorene Compound Represented by Formula (2)

The organooxy group-containing aromatic hydrocarbon ring-modified fluorene compound represented by Formula (2) in which R^{a} and R^{b} are each the group represented by Formula (4) may be produced, for example, by reacting the hydroxy group-containing aromatic hydrocarbon ring-modified fluorene compound represented by Formula (7) and a compound represented by Formula (4-1) below in a solvent (e.g., a ketone solvent such as acetone) in the presence of a base (e.g., an inorganic base such as potassium carbonate).

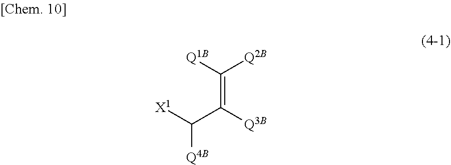

In the formula, X¹ represents a halogen atom, such as chlorine, fluorine, bromine, or iodine, and Q^{1B}, Q^{2B}, Q^{3B}, and Q^{4B} are as defined above.

The organooxy group-containing aromatic hydrocarbon ring-modified fluorene compound represented by Formula (2) in which R^{a} and R^{b} are each the group represented by Formula (5) may be produced, for example, by reacting an oxygen group-containing aromatic hydrocarbon ring-modified fluorene compound represented by Formula (9) below and a compound represented by Formula (5-1) below in a solvent (e.g., an alkyl halide solvent such as dichloromethane) in the presence of a catalyst (e.g., an acid catalyst such as concentrated sulfuric acid).

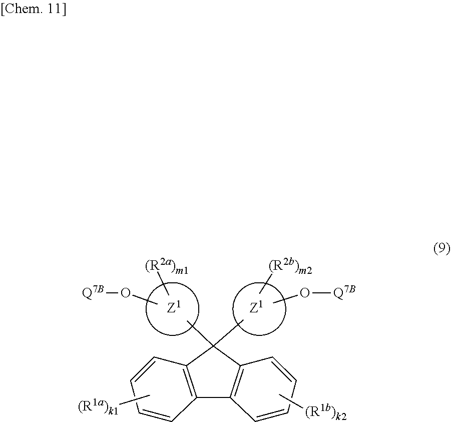

In the formula, Z¹, R^{1a}, R^{1b}, R^{2a}, R^{2b}, k1, k2, m1, m2, and Q⁷B are as defined above.

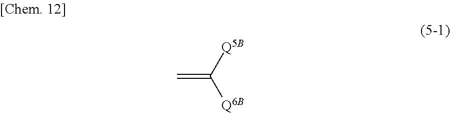

In the formula, Q^{5B} and Q^{6B} are as defined above.

The organooxy group-containing aromatic hydrocarbon ring-modified fluorene compound represented by Formula (2) in which R^{a} and R^{b} are each the group represented by Formula (6) may be produced, for example, by reacting the hydroxy group-containing aromatic hydrocarbon ring-modified fluorene compound represented by Formula (7) and a compound represented by Formula (6-1) below in a solvent (e.g., an ether solvent such as diethyl ether) in the presence of a catalyst (e.g., an acid catalyst such as p-toluenesulfonic acid).

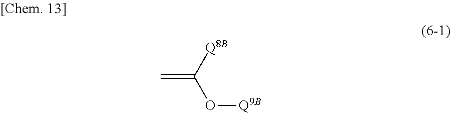

In the formula, Q^{8B} and Q^{9B} are as defined above.
Metal Oxide Nanoparticles Surface-Treated with a Capping Agent

The metal oxide film-forming composition contains metal oxide nanoparticles surface-treated with a capping agent. A single type of metal oxide nanoparticles surface-treated with a capping agent may be used, or two or more types of metal oxide nanoparticles surface-treated with a capping agent or agents may be used in combination. The metal oxide film-forming composition containing the metal oxide nanoparticles surface-treated with a capping agent can easily form a metal oxide film that is less likely to crack when fired at 400° C. or more and has high dry etching resistance.

The metal oxide nanoparticles preferably have an average particle diameter of 5 nm or less, more preferably 4 nm or less, even more preferably 3 nm or less. The average particle diameter of the metal oxide nanoparticles may have any lower limit. For example, the average particle diameter may have a lower limit of 0.5 nm or more, 1 nm or more, or 2 nm or more. With the average particle diameter of the metal oxide nanoparticles falling within such a range, the composition can easily form a metal oxide film that is much less likely to crack when fired at 400° C. or more and has higher dry etching resistance. As used herein, the term “the average particle diameter of the metal oxide nanoparticles” refers to the value measured with a dynamic light scattering (DLS) instrument, such as Malvern Zetasizer Nano S.

The metal oxide nanoparticles may include any metal. Examples of the metal include, but are not limited to, zinc, yttrium, hafnium, zirconium, lanthanum, cerium, neodymium, gadolinium, holmium, lutetium, tantalum, titanium, silicon, aluminum, antimony, tin, indium, tungsten, copper, vanadium, chromium, niobium, molybdenum, ruthenium, rhodium, rhenium, iridium, germanium, gallium, thallium, and magnesium, among which from the viewpoint of film formability and stability, hafnium, zirconium, titanium, and tin are preferred, and zirconium is more preferred. One, two, or more of these metals may be used alone or in combination with one another.

The metal oxide nanoparticles may consist of metal and oxygen atoms or consist of metal and oxygen atoms and additional atoms other than the metal and oxygen atoms. The additional atoms other than the metal and oxygen atoms may be, for example, nitrogen atoms. Specifically, the metal oxide nanoparticles may consist of metal oxide or metal oxynitride.

In the metal oxide film-forming composition according to the present invention, the surfaces of the metal oxide nanoparticles may be partially or entirely covered with a capping agent. The capping agent may include at least one selected from the group consisting of an alkoxysilane, a phenol, an alcohol, a carboxylic acid, and a carboxylic acid halide. In the metal oxide film-forming composition according to the present invention, the metal oxide nanoparticles surface-treated with the capping agent have the ability to be dispersed stably in the solvent and to form a metal oxide film that is less likely to undergo volume contraction when heated at a temperature as low as 400° C. or less.

Examples of the capping agent include alkoxysilanes, such as n-propyltrimethoxysilane, n-propyltriethoxysilane, n-octyltrimethoxysilane, n-octyltriethoxysilane, n-dodecyltrimethoxysilane, n-dodecyltriethoxysilane, n-hexadecyltrimethoxysilane, n-hexadecyltriethoxysilane, n-octadecyltrimethoxysilane, n-octadecyltriethoxysilane, phenyltrimethoxysilane, phenyltriethoxysilane, phenethylphenyltrimethoxysilane, phenethylethyltriethoxysilane, 3-{2-methoxy[poly(ethyleneoxy)]}propyltrimethoxysilane, 3-{2-methoxy[poly(ethyleneoxy)]}propyltriethoxysilane, 3-{2-methoxy[tri(ethyleneoxy)]}propyltrimethoxysilane, 3-{2-methoxy[tri(ethyleneoxy)]}propyltriethoxysilane, vinyltrimethoxysilane, vinyltriethoxysilane, allyltrimethoxysilane, allyltriethoxysilane, 1-hexenyltrimethoxysilane, 1-hexenyltriethoxysilane, 1-octenyltrimethoxysilane, 1-octenyltriethoxysilane, 3-aminopropyltrimethoxysilane, 3-aminopropyltriethoxysilane, 3-mercaptopropyltrimethoxysilane, 3-mercaptopropyltriethoxysilane, 3-acryloyloxypropyltrimethoxysilane, 3-acryloylpropyltriethoxysilane, 3-methacryloyloxypropyltrimethoxysilane, 3-methacryloyloxypropyltriethoxysilane, 3-isocyanatopropyltrimethoxysilane, 3-isocyanatopropyltriethoxysilane, 3-glycidoxypropyltrimethoxysilane, and 3-glycidoxypropyltriethoxysilane; phenols, such as phenol; unsaturated group-free alcohols, such as ethanol, n-propanol, isopropanol, n-butanol, n-heptanol, n-hexanol, n-octanol, n-dodecyl alcohol, n-octadecanol, benzyl alcohol, and triethylene glycol monomethyl ether; unsaturated group-containing alcohols, such as 2-hydroxyethyl (meth)acrylate, 3-hydroxypropyl (meth)acrylate, allyl alcohol, oleyl alcohol, ethylene glycol monoallyl ether, propylene glycol monoallyl ether, and 3-allyoxypropanol; acids, such as octanoic acid, acetic acid, propionic acid, 2-[2-(methoxyethoxy)ethoxy]acetic acid, oleic acid, lauric acid, benzoic acid, 2-acryloyloxyethyl succinic acid, and 2-acryloyloxyethyl phthalic acid; and acid halides of these acids, such as acid chlorides of these acids, among which alkoxysilanes, unsaturated group-containing alcohols, or acids are preferred.

The metal oxide nanoparticles may be surface-treated with any amount of the capping agent. The capping agent is preferably used in an amount enough to react with almost all the hydroxy groups on the surfaces of the metal oxide nanoparticles.

The metal oxide film-forming composition may contain any amount of the metal oxide nanoparticles as long as the object of the present invention is not interfered with. The amount of the metal oxide nanoparticles is preferably 5% by mass or more and 99% by mass or less, more preferably 30% by mass or more and 98% by mass or less, even more preferably 60% by mass or more and 97% by mass or less, based on the total amount of the non-solvent components of the metal oxide film-forming composition. With the amount of the metal oxide nanoparticles falling within such a range, the composition can easily form a metal oxide film that is much less likely to crack when fired at 400° C. or more and has higher dry etching resistance. It should be noted that the amount of the capping agent on the surfaces of the metal oxide nanoparticles is included in the amount of the metal oxide nanoparticles described above.

### Solvent

The metal oxide film-forming composition according to the present invention contains a solvent, which is for controlling applicability or viscosity. The solvent is typically an organic solvent. The organic solvent may be any type in which some components of the metal oxide film-forming composition can be uniformly dissolved or dispersed.

Examples of the organic solvent suitable for use include (poly)alkylene glycol monoalkyl ethers, such as ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether; (poly)alkylene glycol monoalkyl ether acetates, such as ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and propylene glycol monoethyl ether acetate; other ethers, such as diethylene glycol dimethyl ether, diethylene glycol methyl ethyl ether, diethylene glycol diethyl ether, and tetrahydrofuran; ketones, such as methyl ethyl ketone, cyclohexanone, 2-heptanone, and 3-heptanone; alkyl lactates, such as methyl 2-hydroxypropionate and ethyl 2-hydroxypropionate; other esters, such as ethyl 2-hydroxy-2-methylpropionate, methyl 3-methoxypropionate, ethyl 3-methoxypropionate, methyl 3-ethoxypropionate, ethyl 3-ethoxypropionate, ethyl ethoxyacetate, ethyl hydroxyacetate, 2-hydroxy-3-Methylbutanoic acid methyl ester, 3-methyl-3-methoxybutyl acetate, 3-methyl-3-methoxybutyl propionate, ethyl acetate, n-propyl acetate, isopropyl acetate, n-butyl acetate, isobutyl acetate, n-pentyl formate, isopentyl acetate, n-butyl propionate, ethyl butyrate, n-propyl butyrate, isopropyl butyrate, n-butyl butyrate, methyl pyruvate, ethyl pyruvate, n-propyl pyruvate, methyl acetoacetate, ethyl acetoacetate, and ethyl 2-oxobutanoate; aromatic hydrocarbons, such as toluene and xylene; and amides, such as N-methylpyrrolidone, N,N-dimethylformamide, and N,N-dimethylacetamide. One, two, or more of these organic solvents may be used alone or in combination with one another.

The metal oxide film-forming composition according to the present invention may contain any amount of the solvent. From the viewpoint of the applicability and other properties of the metal oxide film-forming composition, the content of the solvent is, for example, 30 to 99.9% by mass, preferably 50 to 98% by mass, based on the total mass of the metal oxide film-forming composition.

### Surfactant

The metal oxide film-forming composition according to the present invention may further contain a surfactant (surface conditioner) for improving applicability, defoaming property, or leveling property. One, two, or more surfactants may be used alone or in combination with one another. Examples of the surfactant include silicone surfactants and fluorosurfactants.

Examples of silicone surfactants include BYK-077, BYK-085, BYK-140, BYK-145, BYK-180, BYK-161, BYK-162, BYK-164, BYK-167, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341, BYK-344, BYK-345, BYK-346, BYK-348, BYK-354, BYK-355, BYK-356, BYK-358, BYK-361, BYK-370, BYK-371, BYK-375, BYK-380, BYK-390, BYK-2050, BYK-2055, BYK-2015, and BYK-9077 (manufactured by BYK Chemie).

Examples of fluorosurfactants include F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF-1132, TF-1027SF, TF-1441, and TF-1442 (manufactured by DIC Corporation); and PolyFox series, such as PF-636, PF-6320, PF-656, and PF-6520 (manufactured by OMNOVA Solutions Inc.).

The metal oxide film-forming composition may contain any amount of the surfactant. From the viewpoint of applicability, defoaming property, and leveling property for the metal oxide film-forming composition, the amount of the surfactant is typically 0.01 to 2% by mass, preferably 0.05 to 1% by mass, based on the total amount of the non-solvent components of the metal oxide film-forming composition.

### Other Components

If necessary, the metal oxide film-forming composition according to the present invention may contain an additive, such as a dispersing agent, a thermal polymerization inhibitor, a defoaming agent, a silane coupling agent, a colorant (e.g., a pigment, a dye), an inorganic filler, an organic filler, a cross-linking agent, or an acid generating agent. These additives may each be a conventionally known one. The surfactant may be an anionic, cationic, or nonionic compound. The thermal polymerization inhibitor may be hydroquinone or hydroquinone monoethyl ether. The defoaming agent may be a silicone compound or a fluoride compound.

The metal oxide film-forming composition according to the present invention may be produced by any method. For example, the metal oxide film-forming composition according to the present invention may be produced by a method that includes uniformly mixing the tertiary alkyloxycarbonyloxy group-containing aromatic hydrocarbon ring-modified fluorene compound represented by Formula (1), the metal oxide nanoparticles surface-treated with the capping agent, the solvent, an optional surfactant, and an optional additional component.

### Method of Producing Metal Oxide Film

The method of producing a metal oxide film according to the present invention includes forming a coating consisting of the metal oxide film-forming composition according to the present invention; and heating the coating.

The coating can be formed, for example, by applying the metal oxide film-forming composition to a substrate, such as a semiconductor substrate. The application may be performed by a method using a contact transfer applicator, such as a roll coater, a reverse coater, or a bar coater, or a non-contact applicator, such as a spinner (e.g., a rotary applicator, a spin coater), a dip coater, a spray coater, a slit coater, or a curtain flow coater. The viscosity of the metal oxide film-forming composition may also be adjusted to fall within an appropriate range, and then the metal oxide film-forming composition may be applied by a printing method, such as an inkjet method or a screen printing method, to form a coating with a desired pattern.

The substrate preferably includes a metal film, a metal carbide film, a metal oxide film, a metal nitride film, or a metal oxynitride film. The metal of which the substrate is made may include silicon, titanium, tungsten, hafnium, zirconium, chromium, germanium, copper, aluminum, indium, gallium, arsenic, palladium, iron, tantalum, iridium, molybdenum, or any alloy thereof. The metal preferably includes silicon, germanium, or gallium. The substrate may have a surface with asperities. Such a surface with asperities may be made of a patterned organic material.

If necessary, the coating may then be dried by removing volatile components including the solvent. The coating may be dried by any method. For example, the coating may be dried by a method that includes drying the coating on a hot plate at a temperature of 80° C. or more and 140° C. or less, preferably at a temperature of 90° C. or more and 130° C. or less, for a time period of 60 seconds or more and 150 seconds or less. Before the heating with a hot plate, the coating may be dried under reduced pressure at room temperature using a vacuum chamber dryer (VCD).

After being formed in this way, the coating is heated. The temperature at which the coating is heated is preferably, but not limited to, 400° C. or more, more preferably 420° C. or more, even more preferably 430° C. or more. The upper limit of the heating temperature may be set to any appropriate value. The upper limit of the heating temperature may be, for example, 600° C. or less, and is preferably 550° C. or less for etching rate control or in-plane uniformity during dry etching. Typically, the heating time period is preferably 30 seconds or more and 150 seconds or less, more preferably 60 seconds or more and 120 seconds or less. The heating step may be performed at a single heating temperature or may include two or more stages with different heating temperatures.

In the heating step, the mechanism shown below may work to form a metal oxide film that is less likely to crack when fired at 400° C. or more. At a stage where the heating temperature reaches about 180 to about 220° C. after the start of heating, elimination of a moiety corresponding to the protecting group, such as the tertiary alkyloxycarbonyl group, from the aromatic hydrocarbon ring-modified fluorene compound represented by Formula (1) or (2) may occur to form the hydroxy group-containing aromatic hydrocarbon ring-modified fluorene compound represented by Formula (7) or to form a carboxy group-containing aromatic hydrocarbon ring-modified fluorene compound having a structure with an oxycarboxy group substituted for the hydroxy group in Formula (7). As a result, an interaction, such as cross-linking, may occur between the surface of the metal oxide nanoparticles and the aromatic hydrocarbon ring-modified fluorene compound resulting from the elimination of the protecting group. Thus, even when the capping agent is eliminated by further heating, for example, at 400° C. or more, the effect of such an interaction would enable the formation of a metal oxide film resistant to cracking. On the other hand, if an alternative organic component that does not undergo deprotection upon heating is used, such as poly(methyl methacrylate) or polystyrene, the organic component will dissipate without causing an interaction, such as cross-linking, during the heating, so that film cracking caused by firing at 400° C. or more would be observed.

The metal oxide film formed as described above is suitable for use as, for example, a metal hard mask or a material for pattern reversal. The metal oxide film may have any appropriate thickness selected depending on the intended use. The thickness of the metal oxide film is preferably 1 nm or more and 40 μm or less, more preferably 10 nm or more and 20 μm or less, even more preferably 20 nm or more and 10 μm or less.

### Examples

Hereinafter, the present invention will be described in more detail with reference to examples, which are not intended to limit the scope of the present invention.

### Preparation of Metal Oxide Film-Forming Compositions

### Organic Components

BNF-B: A modified bisnaphthol fluorene compound represented by Formula 1-A below

The modified bisnaphthol fluorene compound represented by Formula 1-A was obtained by reacting a bisnaphthol fluorene represented by Formula 3-A below and di-tert-butyl dicarbonate represented by Formula 4-A below in dichloromethane in the presence of N,N-dimethyl-4-aminopyridine.

BPF-B: A modified bisphenol fluorene compound represented by Formula 1-B below

The modified bisphenol fluorene compound represented by Formula 1-B was obtained by reacting a bisphenol fluorene represented by Formula 3-B below and di-tert-butyl dicarbonate represented by Formula 4-A in dichloromethane in the presence of N,N-dimethyl-4-aminopyridine.

PMMA: Poly(methyl methacrylate) (weight average molecular weight: 10,000)
Pst: Polystyrene (weight average molecular weight: 10,000)
PDA-TPA: An aromatic polyamide resin (weight average molecular weight: 10,000) obtained by polycondensation of p-phenylenediamine with terephthalic acid
BNF: A bisnaphthol fluorene represented by Formula 3-A below

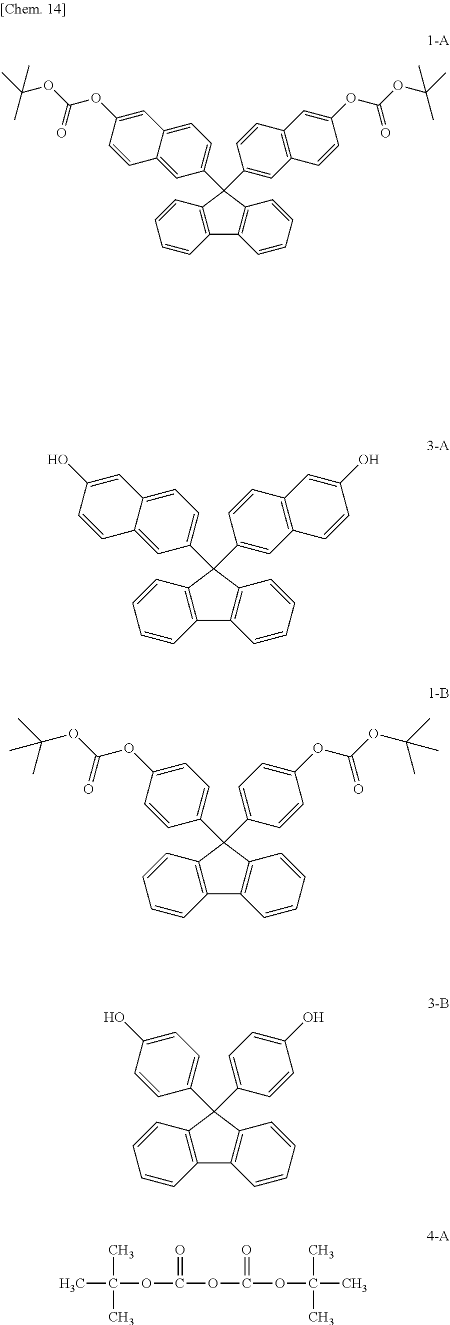

### Metal Oxide Nanoparticles

ZrO₂ particles 1: ZrO₂ particles surface-treated with a capping agent HOA

According to the description in paragraph [0223] of Japanese Unexamined Patent Application Publication No. 2018-193481, a ZrO₂ slurry obtained after cooling to room temperature was centrifuged to give a wet cake A. To the wet cake A was added 2-hydroxyethyl acrylate as a capping agent (HOA (trade name) manufactured by Kyoeisha Chemical Co., Ltd. (hereinafter also simply referred to as “HOA”)) in an amount 0.3 times the mass of the wet cake A, and stirred. The mixture was subjected to reprecipitation and then centrifuged to give a wet cake B. The wet cake B was dried under reduced pressure overnight to give ZrO₂ particles (average particle diameter 2.5 nm) surface-treated with the capping agent HOA, which were in the form of a powder.

ZrO₂ particles 2: ZrO₂ particles surface-treated with a capping agent A-SA

Instead of HOA, 2-acryloyloxyethyl succinic acid (see the formula below (hereinafter also simply referred to as “A-SA”)) was added as the capping agent to the wet cake A. ZrO₂ particles (average particle diameter 2.5 nm) surface-treated with the capping agent A-SA were obtained in the form of a powder as in the case of ZrO₂ particles 1 except that A-SA was used in an amount 0.2 times the mass of the wet cake A.

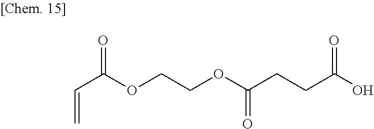

ZrO₂ particles 3: ZrO₂ particles surface-treated with a silane compound as a capping agent.

According to the description in paragraph [0223] of Japanese Unexamined Patent Application Publication No. 2018-193481, nanocrystals surface-treated with a silane compound as a capping agent were obtained in the form of a wet cake. The nanocrystals were dried under reduced pressure overnight to give ZrO₂ particles (average particle diameter 8 nm) surface-treated with the silane compound capping agent, which were in the form of a powder.

TiO₂ particles 1: TiO₂ particles surface-treated with the capping agent HOA

Ti(OiPr)₄ was used as a starting material, from which a TiO₂ slurry was obtained, instead of the ZrO₂ slurry, by a method similar to that in the case of ZrO₂ particles 1. The slurry was centrifuged to give a wet cake C. To the wet cake C was added the capping agent HOA in an amount 0.3 times the mass of the wet cake C, and stirred. The mixture was subjected to reprecipitation and then centrifuged to give a wet cake D. The wet cake D was dried under reduced pressure overnight to give TiO₂ particles (average particle diameter 3.0 nm) surface-treated with the capping agent HOA, which were in the form of a powder.

HfO₂ particles 1: HfO₂ particles surface-treated with the capping agent HOA

Hf(OiPr)₄ was used as a starting material, from which a HfO₂ slurry was obtained, instead of the ZrO₂ slurry, by a method similar to that in the case of ZrO₂ particles 1. The slurry was centrifuged to give a wet cake E. To the wet cake E was added the capping agent HOA in an amount 0.3 times the mass of the wet cake E, and stirred. The mixture was subjected to reprecipitation and then centrifuged to give a wet cake F. The wet cake F was dried under reduced pressure overnight to give HfO₂ particles (average particle diameter 3.0 nm) surface-treated with the capping agent HOA, which were in the form of a powder.

SnO₂ particles 1: SnO₂ particles surface-treated with the capping agent HOA

Sn(OBt)₄ was used as a starting material, from which a SnO₂ slurry was obtained, instead of the ZrO₂ slurry, by a method similar to that in the case of ZrO₂ particles 1. The slurry was centrifuged to give a wet cake G. To the wet cake G was added the capping agent HOA in an amount 0.3 times the mass of the wet cake G, and stirred. The mixture was subjected to reprecipitation and then centrifuged to give a wet cake H. The wet cake H was dried under reduced pressure overnight to give SnO₂ particles (average particle diameter 3.0 nm) surface-treated with the capping agent HOA, which were in the form of a powder.

### Solvent

PGMEA: Propylene glycol monomethyl ether acetate

Table 1 shows the types of the organic component, the metal oxide nanoparticles, and the solvent and their proportions (units: parts by mass) used for each composition. As shown in Table 1, the organic component, the metal oxide nanoparticles, and the solvent were mixed and stirred, and the resulting mixture was filtered through a membrane filter (0.2 μm in pore diameter) to give the composition.

### Preparation of Metal Oxide Film

The composition was placed dropwise onto a 6-inch silicon wafer and spin-coated on the wafer. Subsequently, the coated wafer was pre-baked on a hot plate at 100° C. for 120 seconds and then post-baked on a hot plate at 450° C. for 90 seconds, so that a metal oxide film about 30 nm in thickness was obtained from the coating. The cross-section of the metal oxide film was observed with a scanning electron microscope (SEM) when the film thickness was determined.

### Evaluation of Cracking

The surface of the metal oxide film was observed with SEM and evaluated for cracking based on the criteria shown below. The results are shown in Table 1.

+ (Good): No cracking was observed on the surface of the metal oxide film.
− (Poor): Cracking was observed on the surface of the metal oxide film.

### Evaluation of Dry Etching Rate

The metal oxide film was dry-etched for 3 minutes in TCA-2400 (manufactured by Tokyo Ohka Kogyo Co., Ltd.) under the conditions: pressure 66.6 Pa, power 300 W, and 02 gas 200 mL/min, when the dry etching rate was measured and evaluated based on the criteria shown below. The results are shown in Table 1.

+ (Good): The dry etching rate was 25 nm/min or less.
− (Poor): The dry etching rate was more than 25 nm/min.

### Evaluation of Coating Quality

The surface of the metal oxide film was observed with SEM and evaluated for coating quality based on the criteria shown below. The results are shown in Table 1.

+ (Good): No asperities were observed on the surface of the metal oxide film.
− (Poor): Asperities were observed on the surface of the metal oxide film.

TABLE 1

| | Organic | Metal oxide | | | Dry etching | Coating |
|---|---|---|---|---|---|---|
| | component | nanoparticles | Solvent | Cracking | rate | quality |
| Example 1 | BNF-B/0.7 | ZrO₂ particles 1/3.3 | PGMEA/96.0 | + | + | + |
| Example 2 | BNF-B/0.7 | ZrO₂ particles 2/3.3 | PGMEA/96.0 | + | + | + |
| Example 3 | BNF-B/0.7 | ZrO₂ particles 3/3.3 | PGMEA/96.0 | + | + | + |
| Example 4 | BPF-B/0.7 | ZrO₂ particles 1/3.3 | PGMEA/96.0 | + | + | + |
| Example 5 | BNF-B/0.7 | TiO₂ particles 1/3.3 | PGMEA/96.0 | + | + | + |
| Example 6 | BNF-B/0.7 | HfO₂ particles 1/3.3 | PGMEA/96.0 | + | + | + |
| Example 7 | BNF-B/0.7 | SnO₂ particles 1/3.3 | PGMEA/96.0 | + | + | + |
| Comparative | PMMA/0.7 | ZrO₂ particles 1/3.3 | PGMEA/96.0 | − | + | − |
| Example 1 | | | | | | |
| Comparative | Pst/0.7 | ZrO₂ particles 1/3.3 | PGMEA/96.0 | − | + | + |
| Example 2 | | | | | | |
| Comparative | PDA-TPA/0.7 | ZrO₂ particles 1/3.3 | PGMEA/96.0 | + | − | − |
| Example 3 | | | | | | |
| Comparative | BNF/0.7 | ZrO₂ particles 1/3.3 | PGMEA/96.0 | − | + | + |
| Example 4 | | | | | | |

Table 1 indicates that the metal oxide film of each of the examples is resistant to cracking upon firing at 400° C. or more and has high dry etching resistance whereas the metal oxide film of each of the comparative examples is not resistant to cracking upon firing at 400° C. or more or has low dry etching resistance.

What is claimed is:

1. A metal oxide film-forming composition comprising:
a tertiary alkyloxycarbonyloxy group-containing aromatic hydrocarbon ring-modified fluorene compound represented by Formula (1) below;
metal oxide nanoparticles surface-treated with a capping agent; and
a solvent, 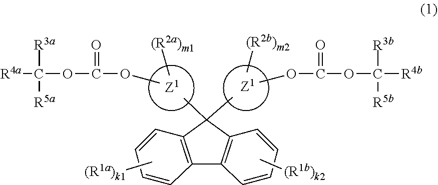
wherein ring Z¹ represents an aromatic hydrocarbon ring,
R^{1a} and R^{1b} each independently represents a halogen atom, a cyano group, or an alkyl group,
R^{2a} and R^{2b} each independently represents an alkyl group,
R^{3a}, R^{3b}, R^{4a}, R^{4b}, R^{5a}, and R^{5b} each independently represents an alkyl group having 1 to 8 carbon atoms,
k1 and k2 each independently represents an integer of 0 or more and 4 or less, and
m1 and m2 each independently represents an integer of 0 or more and 6 or less.

2. A metal oxide film-forming composition comprising:
an aromatic hydrocarbon ring-modified fluorene compound having a carboxy or hydroxy group-protecting group;
metal oxide nanoparticles surface-treated with a capping agent; and
a solvent.

3. The metal oxide film-forming composition according to claim 2, wherein the aromatic hydrocarbon ring-modified fluorene compound is a tertiary alkyloxycarbonyloxy group-containing aromatic hydrocarbon ring-modified fluorene compound represented by Formula (1) below and/or an organooxy group-containing aromatic hydrocarbon ring-modified fluorene compound represented by Formula (2) below, 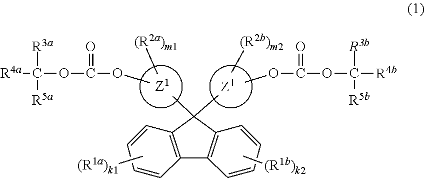
wherein ring Z¹ represents an aromatic hydrocarbon ring,
R^{1a} and R^{1b} each independently represents a halogen atom, a cyano group, or an alkyl group,
R^{2a} and R^{2b} each independently represents an alkyl group,
R^{3a}, R^{3b}, R^{4a}, R^{4b}, R^{5a}, and R^{5b} each independently represents an alkyl group having 1 to 8 carbon atoms,
k1 and k2 each independently represents an integer of 0 or more and 4 or less, and
m1 and m2 each independently represents an integer of 0 or more and 6 or less, 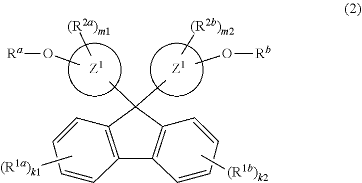
wherein ring Z¹, R^{1a}, R^{1b}, R^{2a}, R^{2b}, k1, k2, m1, and m2 are as defined above, and
R^{a} and R^{b} are each independently a group represented by Formula (4), (5), or (6) below, 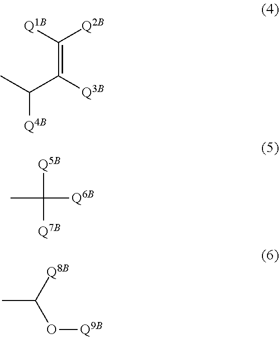
wherein Q^{1B}, Q^{2B}, Q^{3B}, and Q^{4B} are each a hydrogen atom or an alkyl group having 1 to 20 carbon atoms, any two selected from substituents represented by Q^{1B}, Q^{2B}, Q^{3B}, and Q^{4B} may be bonded to each other to form a cyclic substituent,
Q^{5B}, Q^{6B}, and Q^{7B} are each an alkyl group having 1 to 20 carbon atoms, any two selected from substituents represented by Q^{5B}, Q^{6B}, and Q^{7B} may be bonded to each other to form a cyclic substituent,
Q^{8B} and Q^{9B} are each an alkyl group having 1 to 20 carbon atoms, and Q^{8B} and Q^{9B} may be bonded to each other to form a cyclic substituent.

4. The metal oxide film-forming composition according to claim 1, wherein R^{3a}, R^{3b}, R^{4a}, R^{4b}, R^{5a}, and R^{5b} are each a methyl group.

5. The metal oxide film-forming composition according to claim 3, wherein R^{3a}, R^{3b}, R^{4a}, R^{4b}, R^{5a}, and R^{5b} are each a methyl group.

6. The metal oxide film-forming composition according to claim 1, wherein the metal oxide nanoparticles comprise at least one metal selected from the group consisting of zinc, yttrium, hafnium, zirconium, lanthanum, cerium, neodymium, gadolinium, holmium, lutetium, tantalum, titanium, silicon, aluminum, antimony, tin, indium, tungsten, copper, vanadium, chromium, niobium, molybdenum, ruthenium, rhodium, rhenium, iridium, germanium, gallium, thallium, and magnesium.

7. The metal oxide film-forming composition according to claim 2, wherein the metal oxide nanoparticles comprise at least one metal selected from the group consisting of zinc, yttrium, hafnium, zirconium, lanthanum, cerium, neodymium, gadolinium, holmium, lutetium, tantalum, titanium, silicon, aluminum, antimony, tin, indium, tungsten, copper, vanadium, chromium, niobium, molybdenum, ruthenium, rhodium, rhenium, iridium, germanium, gallium, thallium, and magnesium.

8. A method of producing a metal oxide film, the method comprising:
forming a coating comprising the metal oxide film-forming composition according to claim 1; and
heating the coating.

9. A method of producing a metal oxide film, the method comprising:
forming a coating comprising the metal oxide film-forming composition according to claim 2; and
heating the coating.

10. The method according to claim 8, wherein the heating comprises heating at a temperature of 400° C. or more.

11. The method according to claim 9, wherein the heating comprises heating at a temperature of 400° C. or more.

12. The method according to claim 8, wherein the metal oxide film forms a metal hard mask.

13. The method according to claim 9, wherein the metal oxide film forms a metal hard mask.
